(19) United States
(12) Patent Application Publication
(10) Pub. No.: US 2021/0291449 A1
(43) Pub. Date: Sep. 23, 2021

(54) METHOD FOR PRODUCING A THREE-DIMENSIONAL OBJECT BY A MULTIPHOTON PHOTOPOLYMERIZATION PROCESS AND ASSOCIATED DEVICE

(71) Applicants: ECOLE CENTRALE DE MARSEILLE, Marseille (FR); UNIVERSITÉ D'AIX-MARSEILLE, MARSEILLE Cedex 7 (FR); CENTRE NATIONAL DE LA RECHERCHE SCIENTIFIQUE, Paris (FR)

(72) Inventors: Jean-Claude ANDRE, Nancy (FR); Laurent GALLAIS-DURING, Pertuis (FR); Claude AMRA, Marseille (FR)

(21) Appl. No.: 16/336,640

(22) PCT Filed: Sep. 27, 2017
(86) PCT No.: PCT/FR2017/052622

§ 371 Date: Mar. 26, 2019

(30) Foreign Application Priority Data
Sep. 28, 2016 (FR) 1659211

(51) Int. Cl. B29C 64/268; B29C 64/165; G03F 7/20; G03F 7/038

(52) U.S. Cl. CPC B29C 64/268; B29C 64/165; B33Y 70/10; G03F 7/038; G03F 7/2053; G03F 7/70416

(57) ABSTRACT

The present invention relates to a method for producing a three-dimensional object comprising the following operations: a. introducing a composition (11) into a polymerization vessel (9), b. polymerizing the composition (11) by multiphoton photopolymerization, at predetermined locations, in order to produce the three-dimensional object (3), the composition (11) comprising at least one monomer, at least one filler and at least one photoinitiator, —characterized in that: the difference between the refractive indices of the monomer and of the filler present is less than 0.05; —the viscosity of the composition (11) is greater than or equal to 0.05 Pa·s; —the composition (11) is transparent to the photopolymerization wavelength.

### RELATED APPLICATIONS

This application is the national stage of PCT/FR2017/052622, which was filed on Sep. 27, 2017, which claims the benefit of the Sep. 28, 2016 priority date of French Application 1659211, the contents of which are herein incorporated by reference.

### FIELD OF THE INVENTION

The present invention relates to a process for producing a three-dimensional object and to a device for implementing this process.

### BACKGROUND AND PRIOR ART

There has been a considerable craze for 3D printing technologies since the first uses thereof in the middle of the 1980s.

Known in particular from patent FR 2 567 668 is a device for producing models of industrial parts. This device makes it possible to produce parts by sweeps of successive horizontal planes, the sweep being carried out from the bottom to the top of the vessel containing the monomer liquid. [ow] The 3D printing or three-dimensional printing techniques commonly used are based on a similar principle, i.e. that the object is obtained sequentially by the superposition of layers or by sequential provision of material.

Among the various 3D printing processes, FDM (fused deposition modeling), SLA (stereolithography) and selective laser sintering (a laser agglomerates a layer of powder) are more particularly distinguished.

These techniques have been considerably improved in recent years so that they are no longer only used for producing prototypes, but increasingly often for producing functional objects.

Stereolithography by photopolymerization is a 3D printing technique that makes it possible to manufacture a three-dimensional object by a succession of layers of photopolymerizable resin. The object is manufactured in a bath of liquid resin, the resin generally being polymerized by radical polymerization starting from a composition of acrylate monomers or by cationic polymerization starting from an epoxy composition and a photoinitiator, which enables the polymerization under the effect of light irradiation. Certain compositions suitable for single-photon stereolithography applications are commercially available. These compositions comprise monomers, typically acrylates or epoxies and the initiator.

A mobile platform is generally submerged in a vessel of liquid resin and supports the object in the process of being fabricated. The platform is positioned at a certain depth below the level of the resin.

A laser beam is directed onto the surface of the liquid resin in order to carry out a suitable sweep in order to photopolymerize the resin and form a slice of the object to be fabricated.

After treating one slice, the platform descends by a predefined distance corresponding to the thickness of one slice and the process is repeated for each slice, thus making it possible to obtain the complete 3D structure of the object.

Once completed, the object is removed from the vessel, washed, and the holding elements are removed mechanically. The unpolymerized liquid resin present in the vessel may subsequently be recovered.

Depending on the resin used, a final step of curing the object may be applied in order to harden it.

These techniques have the drawback of not allowing the production of very thin layers, typically of the order of several tens of μm or even less than a micron, which present the risk of moving or of being torn during the fabrication of the object.

Furthermore, these 3D printing techniques by superposition of layers do not enable the fabrication of complex objects or objects that require a high degree of finishing. This is in particular due to the viscosity of the resin and to the surface tension thereof. As a general rule, a resin with a low viscosity, generally of the order of several tens or hundreds of cP (centipoise) is preferred, since it facilitates the positioning of the layers.

Added to this is the fact that it is also necessary to fabricate holding elements such as one or more support(s), for example stems, which will be removed once the object is removed from the resin, in order to hold the object under construction in the vessel.

These holding elements prove necessary due to the low viscosity of the resin and the liquid nature thereof. An object created in a low-viscosity resin with no support or holding elements would have a tendency to move (this would only be during the addition of a layer of resin), which makes the fabrication of the object difficult, or even impossible.

Depending on the complexity of the object to be produced, some of these supports cannot be removed easily and, in certain cases, the objects cannot be fabricated. The production of holding elements or of fabrication appendages, the sole purpose of which is to enable the fabrication of the object, further increases the design time, fabrication time and finishing time.

Furthermore, for objects requiring a finished surface appearance, it is necessary to use a fabrication resolution suitable for the desired surface finish or to carry out an additional treatment such as machining.

In order to avoid these limitations, it is possible to resort to multiphoton photopolymerization (2PSL) techniques, in particular two-photon photopolymerization techniques.

Two-photon photopolymerization techniques have, for example, been developed by Shoji Maruo, Osamu Nakamura, and Satoshi Kawata, “Three-dimensional microfabrication with two-photon-absorbed photopolymerization,” Opt. Lett. 22, 132-134 (1997).

These techniques consist in directly attaining, using an optical pointer advantageously formed by a focused laser beam, a designated location in a volume in order to polymerize the resin at this location. An object may thus be fabricated continuously by directing the focused laser beam into the volume of the vessel containing the composition without it being necessary to fabricate the object via successive slices or layers.

The production of 3D objects by multiphoton photopolymerization thus makes it possible to produce objects of great complexity with a high degree of finishing, which may be of the order of a nanometer.

These 2PSL printing techniques require the use of initiators capable of absorbing two photons sequentially or simultaneously in order to form reactive species for initiating the polymerization.

Since two-photon absorption requires, depending on the material, a high light density, of the order of around a hundred mJ/cm² at the focal point, the photopolymerization is limited to the immediate vicinity of the focal point of the laser, where the light density is relatively high in order to activate the initiator.

One of the main advantages of two-photon stereolithography (2PSL) is to enable the fabrication of three-dimensional objects without it being necessary to fabricate the object as superposed slices or layers.

This fixed resolution is defined by the dimension of the elementary volume, or voxel, produced by laser pulse. Voxel is the acronym for “volumetric pixel”. If it is desired to have a good resolution without additional treatment, when the object to be fabricated requires a high resolution, this leads to very long fabrication times and operating costs which are possibly prohibitive. This is why this 2PSL technique is generally limited to small-sized objects, often in the millimeter, or even micrometer or nanometer range.

Furthermore, this technique makes it necessary to use a high light density at the focal point which is generally of micrometer size and which is not therefore optimized for the fabrication of centimeter-sized objects, i.e. objects inscribed within a volume typically between around 1 and 1000 cm³.

More recently, 2PSL techniques with variable resolution have been developed. Known from the document “Stereolithography with variable resolutions using optical filter with high contrast-gratings” Li et al., J. Vac. Sci. Technol. B, Vol. 33, No 6, November/December 2015, is a stereolithography 3D printing method. The variation of the resolution being obtained by the use of optical filters that modify the wavelength of the laser beam, enabling a variable pixel size of 37 and 417 μm. This method has the drawback of using 2 different wavelengths and therefore of only enabling 2 pixel sizes as a function of the wavelength of the laser beam and of the optical filter. Furthermore, this technique only remains suitable for objects of micrometer size.

The document “Using variable beam spot scanning to improve the SL process”, Yi et al., Rapid Prototyping Journal, Vol. 19, No 2, 2013, pages 100-110, describes a stereolithography method with variable resolution. The variation of the resolution being obtained by an optical device. This method makes it possible to form objects of centimeter size. However, this method has many drawbacks and requires a considerable optimization of the device as a function of the objects to be produced. Although it is possible with this process to change the size of the voxel in two dimensions, this is not possible in the third dimension, perpendicular to the first two, for example in the depth dimension.

More recently, so-called bio-printing processes have been developed for the fabrication of living tissues, or even organs. These methods are in particular described in the following publications.
André J. C., Malaquin L., Guédon E. (2017) “Bio-printing; où va-t-on?” [Bio-printing; where are we heading?], Techniques de I'Ingénieur—ref. RE268 V1, 23 pp. (2017).
Chua C. K., Yeong N.Y. (2015) “Bio-printing: principles and applications” e-book World Scientific Ed.—Singapore.
Morimoto Y., Takeuchi S. (2013) “3D cell culture based on microfluidic technique to mimic living tissues” Biomatter. Sci., 1, 257-264.

These bio-printing processes are additive manufacturing processes using living cells combined with supports fabricated for example by stereolithography.

One of the drawbacks of these processes is that they generate shearing movements during the positioning of the successive layers, and these movements are capable of damaging the living cells and of adversely affecting their survival.

The present invention aims to at least partially overcome the various abovementioned drawbacks by providing a three-dimensional printing process using multiphoton photopolymerization (2PSL), in particular two-photon photopolymerization, which is more effective for the production of objects of centimeter size.

### SUMMARY OF THE INVENTION

For this purpose, the present invention provides a process for producing a three-dimensional object comprising the following operations:

a. introducing a composition into a polymerization vessel,
b. polymerizing the composition by multiphoton photopolymerization, at predetermined locations, in order to produce the three-dimensional object, the composition comprising at least one monomer, at least one filler and at least one photoinitiator,
wherein the difference between the refractive indices of the monomer and of the filler present is less than 0.05;
the viscosity of the composition is greater than or equal to 0.05 Pa·s;
the composition is transparent to the photopolymerization wavelength.

After the production of the three-dimensional object, the latter is removed from the vessel and washed in a solution that makes it possible to eliminate the unpolymerized composition from the three-dimensional object. The solution being for example isopropanol and/or acetone.

By means of the invention, there is a significant increase in efficiency for producing centimeter-size objects. Furthermore, it is possible to dispense with fabrication artifacts, i.e. the production of holding elements or appendages or supports that have to be removed once the three-dimensional is finished.

The process according to the invention may, furthermore, have one or more of the following features taken alone or in combination:
the composition has a viscosity value greater than or equal to 0.30 Pa·s;
the filler comprises transparent particles;
the composition comprises from 10 to 70% by volume of transparent particles;
the transparent particles are of spherical shape;
the transparent particles are made of silica, of glass, in particular of borosilicate glass or of soda-lime glass;
the transparent particles are made of organic material, in particular with polymers that are insoluble in the resin;
the filler comprises at least one component that is soluble in the composition;
the composition comprises monomers selected from L-lactic acid, glycolic acid, caprolactones, considered alone or as a mixture, fillers comprising living cells, a hydrogel selected from collagen, gelatin, fibrin, alginate, chitin, chitosan, hyaluronic acid, poly-(2-hydroxyethyl methacrylate) (PHEMA), polyvinyl alcohol (PVA) and polyethylene glycol (PEG) considered alone or as a mixture;
the monomer is an acrylic monomer;
the acrylic monomer is selected from the following group: poly(ethylene glycol) diacrylate, tri(ethylene glycol) dimethacrylate, pentaerythritol tetraacrylate, 1,6-hexanediol diacrylate, or in combination;
the photoinitiator(s) is (are) selected from the following group: aromatic ketones, aromatic derivatives, eosin Y and other xanthene dyes;
the composition comprises at least one epoxy monomer;
the photoinitiator is an onium salt;
the multiphoton photopolymerization is carried out using a laser beam, wherein the polymerization spatial resolution is adapted by placing an optical diffuser, in particular between 1° and 20°, in the laser beam;
the three-dimensional object comprises an outer surface and an inner volume and wherein localized locations in the inner volume are polymerized with a lower resolution than the locations forming the outer surface(s) of the three-dimensional object;
various portions of the three-dimensional object are successively polymerized in various vessels each containing a specific composition that makes it possible to obtain a voxel size, or even functionalities that are predetermined;
the inner volume is polymerized in a first vessel containing a first composition comprising first fillers in the form of transparent particles making it possible to obtain a first voxel size and the outer part of the object is polymerized in a second vessel containing a second composition comprising second fillers in the form of transparent particles or no filler making it possible to obtain a second voxel size, smaller than the first voxel size.

According to another embodiment, the invention may be adapted for bio-printing operations.

The use of the process according to the invention has the advantage of not generating shearing movement thus improving the bio-printing processes. Moreover, the cells are less sensitive to radiation of large wavelength, typically of the order of 300 to 360 nm for conventional printing processes and of the order of 550 nm for 2PSL technologies, which makes it possible to allow a better survival of the living elements present in a photopolymerizable biocompatible organic composition. 20 [0045] The invention also relates to a device for producing a three-dimensional object by multiphoton, in particular two-photon, photopolymerization, comprising:
a laser emitting a laser beam,
a polymerization vessel intended to receive a composition as described above,
a device for focusing the laser beam and adapting the numerical aperture thereof,
a displacement unit for enabling the focusing of the laser beam inside the polymerization vessel with a view to polymerizing the composition at the predetermined locations in order to produce the three-dimensional object,
a polymerization resolution adapter comprising at least one diffuser movably mounted on a support in order to be placed on the optical path or outside of the laser beam in order to adapt the polymerization resolution.

### BRIEF DESCRIPTIONS OF THE DRAWINGS

Other advantages and features will become apparent on reading the description of the invention, and also from the following figures, in which:

FIG. 1 is a simplified diagram of an assembly of a system for producing a three-dimensional object,

FIG. 2 is a schematic detailed view of a composition used for the production of a three-dimensional object,

FIG. 3 presents in a table a non-exhaustive list of monomers that can be used in the composition of the invention,

FIG. 4 presents a table of photoinitiators that can be used in the composition of the invention,

FIG. 5 presents a conventional ionic polymerization mechanism with steps of initiation, propagation and transfer,

FIG. 6 presents a diagram of multifunctional monomers of crosslinked systems, which are insoluble in an initial resin,

FIGS. 7A and 7B are photographs respectively representing voxels obtained in the case of a Gaussian beam on the one hand, and voxels obtained by placing a diffuser at the entrance of the objective to control the depth of field of the Gaussian beam on the other hand, the two FIGS. 7A and 7B being to the same scale,

FIG. 8 is a diagram for illustrating the process for producing a three-dimensional object according to one embodiment,

FIG. 9 is a graph representing the measurement of the diameter of the beam as a function of the distance with respect to the objective in the case of the objective alone and in the case of a 1° and 10° diffuser.

In all the figures, identical elements bear the same reference numbers.

The following embodiments are examples. Although the description refers to one or more embodiments, this does not necessarily mean that each reference relates to the same embodiment, or that the features apply only to a single embodiment. Simple features of various embodiments may also be combined and/or interchanged to provide other embodiments.

### DETAILED DESCRIPTION

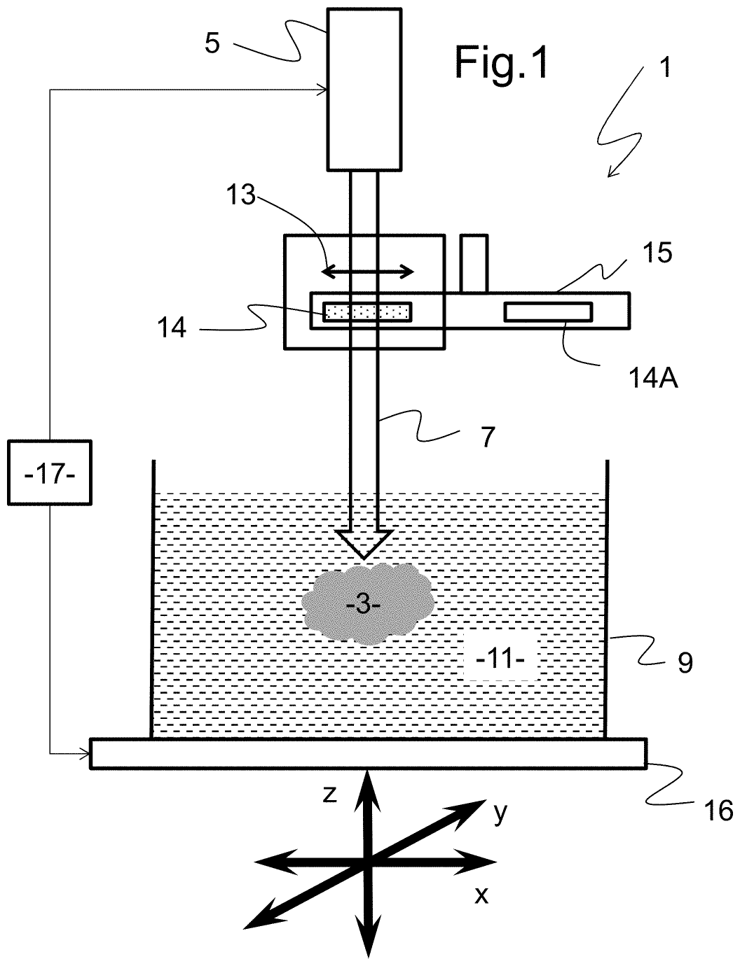

Represented in FIG. 1 is a system 1 for producing a three-dimensional object by multiphoton photopolymerization.

This system 1 comprises a laser 5 emitting a laser beam 7 and a vessel 9, forming a polymerization reactor, intended to receive a composition 11 suitable for multiphoton, in particular two-photon, photopolymerization.

The laser 5 may for example be a pulsed laser and in particular a femto/picosecond laser emitting for example at a wavelength of 1030 nm and coupled, if need be, with non-linear optical crystals that make it possible to double or triple, via a non-linear effect, the frequency of the laser beam in order to obtain a wavelength of nm and/or of 343 nm.

The choice of the light source may depend on the absorption of the composition, which may contain colored additives for example. Thus, other types of pulsed light sources may be used.

The choice of the multiphoton, in particular two-photon, photopolymerization wavelength is determined by the choice of the photochemical initiator and its ability to initiate reactive species under the effect of laser irradiation.

Typically, the output diameter of the beam may be around 2.5 mm, the divergence 0.6 mrad and the polarization linear.

The energy per pulse typically having a duration of 500 fs is between 40 pJ and mJ and the pulse repetition frequency may reach 300 kHz, but may rather be around 1 kHz.

Of course, another laser may be used as long as the wavelength of its beam is suitable and as long as the instantaneous power of the laser makes it possible to carry out the multiphoton, in particular two-photon, photopolymerization of the composition which is in the polymerization vessel 9.

Positioned on the optical path of the laser beam 7 is a focusing optic 13 which may be formed by one or more lenses, in particular an objective for focusing the optical beam inside the composition 11 and adapting the numerical aperture of the beam.

Optionally, a diffuser 14 may be placed on the optical path of the laser beam 7 in order to be able to control the depth of field of the laser beam 7. For this purpose, the system comprises a rotatable support 15 with a through-hole 14A for focusing the laser beam 7 without modification of the beam in the composition 11 and housings in which are mounted respectively various diffusers that make it possible to adapt the depth of field. It is thus possible, as has been introduced, to vary the size of the voxels. The rotatable support 15 with its diffuser(s) 14 and the through-hole 14A makes it possible to adjust the dimensions of the voxels and to obtain a variable resolution in the fabrication process by adjusting the focusing optic and the instantaneous power of the laser beam 7.

The polymerization vessel 9 is, for example, placed on a table 16 movable in x, y and z (see reference points in FIG. 1) to enable the polymerization of the composition 11. In this particular embodiment, it is therefore understood that the focal point does not move, but it is the vessel 9 that is moved in order to position the focal point of the laser at the locations to be photopolymerized. For this, the table 16 is motorized to enable the movement thereof and connected, like the laser, to a control unit 17 which controls both the operation of the laser 5 and the positioning of the table 16.

According to one variant that is not represented, movable mirrors are placed on the optical path of the laser beam 7 to direct the beam to the locations that need to be photopolymerized and a system for focusing the laser and adapting its numerical aperture, making it possible to move the focal point on the axis of propagation. In this case, the movable mirrors are connected to a control unit for directing the laser beam 7.

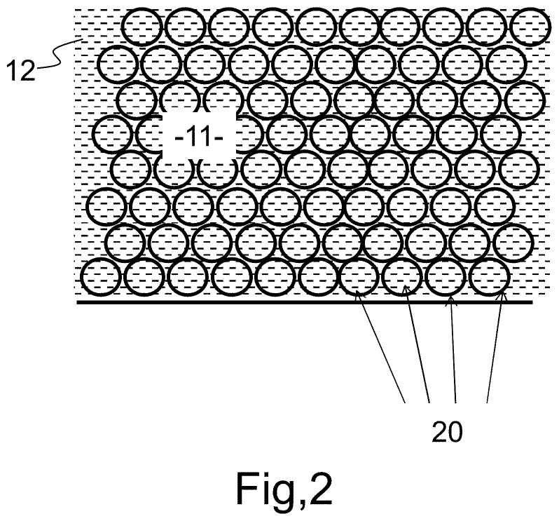

Represented in a simplified and schematic manner in FIG. 2 is the composition 11 for the production of a three-dimensional object 3 via a multiphoton photopolymerization process.

This composition 11 comprising at least one photochemical initiator, at least one monomer 12 and at least one filler 20.

These monomers 12 are transparent to the predetermined wavelength of the pulsed source which is used for the photopolymerization. These monomers have a refractive index nₘₒₙₒₘₑᵣₛ at the predetermined photopolymerization wavelength. A transparent material or medium is understood to mean that the laser beam can pass, at least partly (i.e. it may be weakly absorbent), through this medium as opposed to an opaque material or medium.

A filler 20 is understood to mean a substance or material in the broad sense which is added to the composition 11, but which does not participate in the polymerization reaction. The filler 20 may be considered inert with respect to the polymerization. The fillers 20 are transparent to or very weakly absorbent at the predetermined wavelength of the pulsed source which is used for the photopolymerization. These fillers 20 have a refractive index n_{fillers} at the predetermined photopolymerization wavelength.

The difference between the refractive index nₘₒₙₒₘₑᵣₛ and the refractive index n_{fillers} the fillers 20 is less than 0.05 (|nₘₒₙₒₘₑᵣₛ−n_{fillers}|<0.05), in particular less than 0.025 (|nₘₒₙₒₘₑᵣₛ−n_{fillers}|<0.025) and more particularly less than 0.01 (|nₘₒₙₒₘₑᵣₛ−n_{fillers}|<0.01), or even the refractive index of the monomers 12 and the refractive index of the fillers 20 are equal (|nₘₒₙₒₘₑᵣₛ−n_{fillers}|=0).

By choosing a low, or even zero, difference in refractive indices, this makes it possible to reduce or even eliminate any phenomenon of dispersion of the laser beam 7 in the composition 11, in particular at the interfaces between the monomers and the fillers 20 at the wavelength emitted by the laser.

The refractive index n_{composition} of the composition 11 is the result of all its components Cᵢ, (monomers and fillers 20) in their proportions in the composition.

Thus, if V_{R} is the density of the composition 11 and V_{Ri} is the density of each of the components Cᵢ, and αᵢ is a rational number between 0 and 1, then

$${V}_{R} = {\sum }_{i = 1}^{m} {α}_{i} {V}_{R i}$$

$${\sum }_{i = 1}^{m} {α}_{i} = 1$$

$${n}_{composition} = {\sum }_{i = 1}^{m} {α}_{i} {n}_{1 i}$$

n₁ᵢ being the refractive index of the component Cᵢ.
i,j,m being integers, m corresponding to the number of components Cᵢ constituting the composition 11.

In this case, it is understood that by adjusting the proportions of the components Ci, it is also possible to adjust the refractive index n_{composition} of the composition 11 (and also to adjust the refractive index of the monomer(s) on the one hand relative to the refractive index of the filler on the other hand) if at least one refractive index n₁ᵢ of the component Ci is for example less than the second refractive index n₂ and if at least one refractive index of the component Cj (i≠j) is for example greater than the second refractive index n₂.

The viscosity of the composition 11 may be adjusted by the choice of the volume percentage of the filler 20; to a value of at least 0.05 Pa·s and preferably between 0.30 to 5.00 Pa·s (pascal·second), in order to obtain a stable or set composition, i.e. a composition in which the object in the process of being fabricated, and also the filler 20, does not move.

The filler 20 being for example formed of transparent particles that are insoluble in the composition 11 or of components that are soluble in the composition 11, for example soluble macromolecules such as linear acrylic polymers dissolved in an acrylic resin.

The “solubility” is the ability of a substance, referred to as a solute, to dissolve in another substance, referred to as a solvent, in order to form a homogeneous mixture referred to as a solution. It is therefore simply an ability of two substances relative to one another (to be soluble or insoluble with respect one another).

When the filler 20 comprises insoluble transparent particles, the volume percentage is, preferably, between 10 and 70% by volume, in particular between 30% and 60% and more particularly between 40% and 50%.

When the fillers 20 are transparent particles, they are preferentially of spherical shape and have for example a median diameter of between 10 μm and 1500 μm, in particular between 700 μm and 1200 μm and more specifically of 1000 μm. The minimum size possibly being chosen depending on the diffraction limit, i.e. around 10 times the incident wavelength resulting from the laser.

The transparent particles are, for example, made of molten silica or of glass, in particular of borosilicate glass or of soda-lime glass. The transparent particles may also be organic particles, such as acrylic or epoxy particles.

According to a preferred embodiment of the invention, the transparent particles are monodisperse, i.e. all of the same size.

According to another particular embodiment of the invention, the transparent particles are of variable sizes.

The use of a filler 20 in the form of monodisperse transparent spherical particles also has the advantage of making it possible to define, in certain configurations, the size of the voxels.

Specifically, when the diameter of the spherical particles 20 is greater than the focal volume of the laser beam 7, the size of the voxel is no longer determined by the focal volume of the laser beam 7 but by the diameter of the transparent particles 20.

In particular, the shape of the voxels may thus be perfectly spherical, even though the focal volume of the laser beam 7 is not, the laser beam 7 being used only to agglomerate, at the focal point, the spherical particles which then define the size the voxels.

According to another embodiment of the invention, the composition 11 is a solid composition, for example a composition comprising, as monomers, high molecular weight oligomers that make it possible to obtain a composition that is solid or quasi-solid at ambient temperature, so that it is possible to carry out a photopolymerization of an object without having to produce supporting or holding appendages. After phototransform, the composition 11 may be heated beyond the melting point of the resin in order to separate the object from the resin which gave rise thereto. This has the advantage of significantly reducing the time for producing a three-dimensional object 3 and also of producing highly complex parts that it would be difficult, or even impossible, to fabricate by other methods requiring the positioning of supporting appendages.

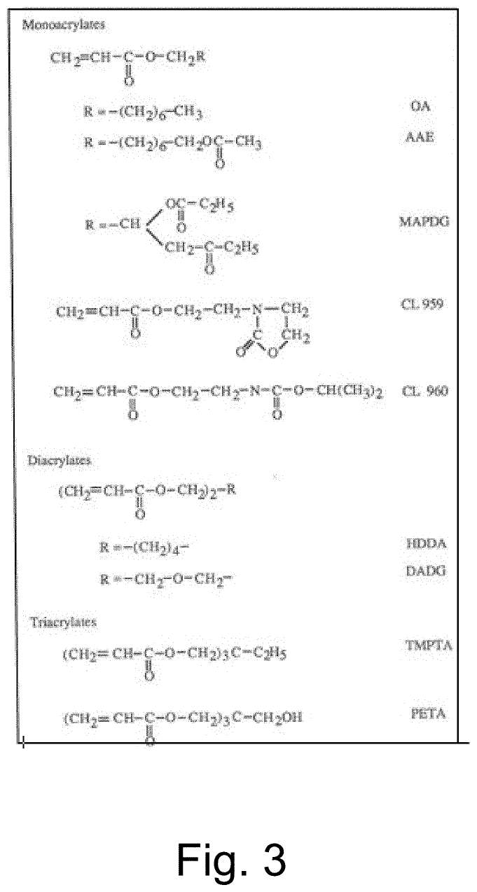

In the case of a liquid composition, the monomers present in the composition are monomers commonly used in 3D printing by single-photon on multiphoton photopolymerization. These monomers are for example acrylic monomers, more specifically acrylates. A non-exhaustive list of monomers that can be used in the composition 11 of the invention is depicted in FIG. 3.

It is noted that the viscosity of the viscous composition (greater than or equal to 0.05 Pa·s=0.5 poise has the effect that the filler, in particular in the form of beads, is virtually set in the composition, i.e. the movement thereof is weak or virtually zero during a time corresponding to a period for producing a three-dimensional object.

Preferentially, the monomers are selected, alone or in combination, from the following monomers: poly(ethylene glycol) diacrylate, tri(ethylene glycol) dimethacrylate, pentaerythritol tetraacrylate, 1,6-hexanediol diacrylate.

The radical photoinitiators contained in the composition 11 must make it possible to initiate the polymerization at the predetermined photopolymerization wavelength. There are a large number of suitable photoinitiators depending on the operating conditions and the choice of which may be easily determined by a person skilled in the art.

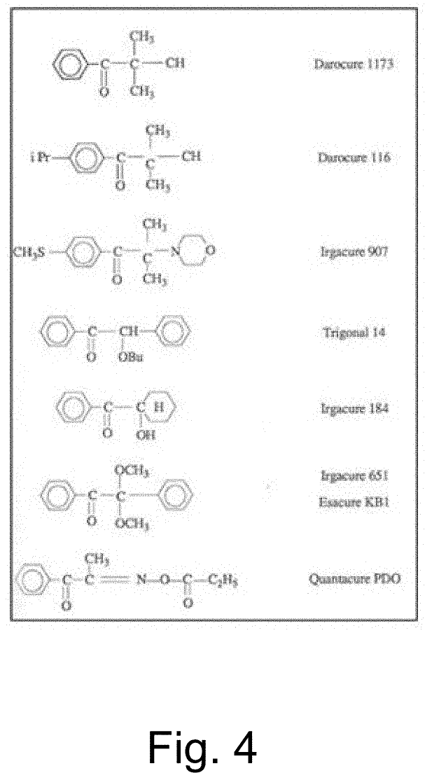

The photoinitiators below are indicated by way of nonlimiting example of the invention. They are typically aromatic ketones, for example 2,2-dimethoxy-1,2-phenylacetophenone (DMPA), sold under the name Irgacure 651 (registered trademark), eosin Y for photopolymerizations in the visible range, or thermal initiators such as benzoyl peroxide for photopolymerizations in the infrared range or else other xanthene dyes. [floss] Photoinitiators particularly suitable for the process according to the invention are represented in FIG. 4 and sold under the trade names (registered trademarks) Darocure 1173 and 116, Quantacure PDO, Irgacure 184, 651 and 907 and Trigonal 14.

Preferentially, the radical photochemical initiator is DMPA sold under the name Irgacure 651 (registered trademark).

According to another embodiment, the process of the invention uses an ionic photopolymerization mechanism, for example a cationic photopolymerization mechanism, in which case the monomers present in the composition 11 are, for example, epoxy monomers and the photoinitiator is an onium salt (for example rhodorsil (registered trademark)). The following reference: Vairon, J.-P.; Spassky, N. Industrial Cationic Polymerization: An Overview, in Cationic Polymerizations; Matyjaszewski, K., Ed.; Marcel Dekker: New York, N.Y., USA, 1996; pp. 683-750 indicates a list of various photochemical initiators that can be used in the process that is the subject of the invention.

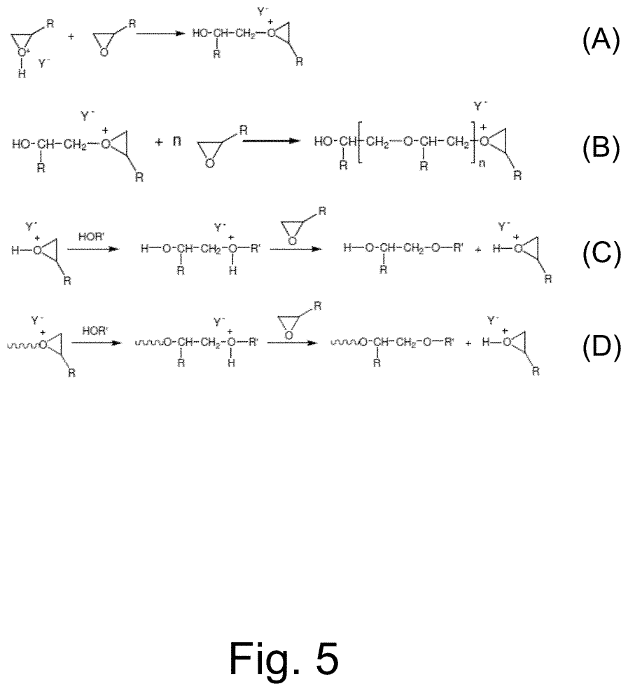

FIG. 5 illustrates a conventional ionic polymerization mechanism with the following steps: initiation (A), propagations (B) and (C), transfer (D).

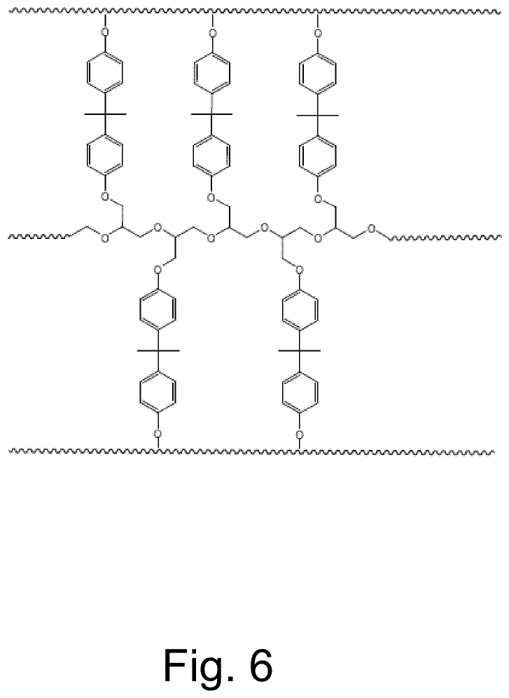

With multifunctional monomers, crosslinked systems, insoluble in the initial resin, may be formed as indicated by the diagram from FIG. 6.

Apart from the compounds from the family of epoxies, it is possible to use a large number of monomers described synthetically in the following reference: Polymers 2013, 5, 361-403; doi: 10.3390/polym5020361 “Ring-Opening Polymerization—An Introductory Review” by Oskar Nuyken and Stephen D. Pask.

As indicated previously, a focusing optic 13 and a diffuser 14 that make it possible to control the depth of field of the laser beam are positioned on the optical path of the laser beam.

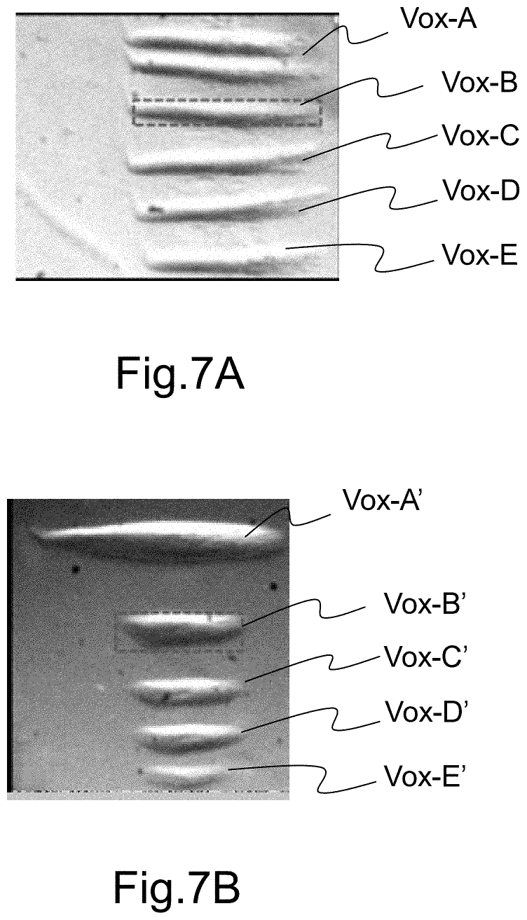

FIG. 7A shows several photopolymerized voxels vox-A, vox-B, vox-C and vox-D, vox-E without diffuser and with various powers.

FIG. 7B shows several photopolymerized voxels vox-A′, vox-B′, vox-C′ and vox-D′, vox-E′, with a diffuser 14 on the optical path of the laser beam 7, and at different beam powers.

The use of a suitable diffuser between 1° and 20° (a 1° diffuser signifies an aperture of the laser beam at the outlet of the diffuser of 1°) makes it possible to vary the size of the photopolymerized voxels. However, obviously, the power of the source must be suitable so that the power density is identical, or as close as possible, to that defined for the voxels of smaller size (substantially varying between the square and the cube of the size of the voxel).

Owing to a high viscosity of the composition 11 (for example >1.00 Pa·s), the process according to the invention makes it possible to envision the production of three-dimensional objects of at least centimeter size without resorting to supporting or holding appendages for objects.

The process according to the invention also makes it possible to reduce the time needed for the production of the three-dimensional object 3 by multiphoton, in particular two-photon, photopolymerization.

Specifically, it is possible to distinguish, in the three-dimensional object 3, an outer surface and an inner volume.

The optimization then consists in polymerizing localized locations in the inner volume (bulk portion) with a low resolution, determined as a function of the object to be printed, and in polymerizing the zones forming the outer surface of the three-dimensional object 3 with a high resolution in order to obtain a surface finish having good quality for the outer surface(s) of the three-dimensional object 3.

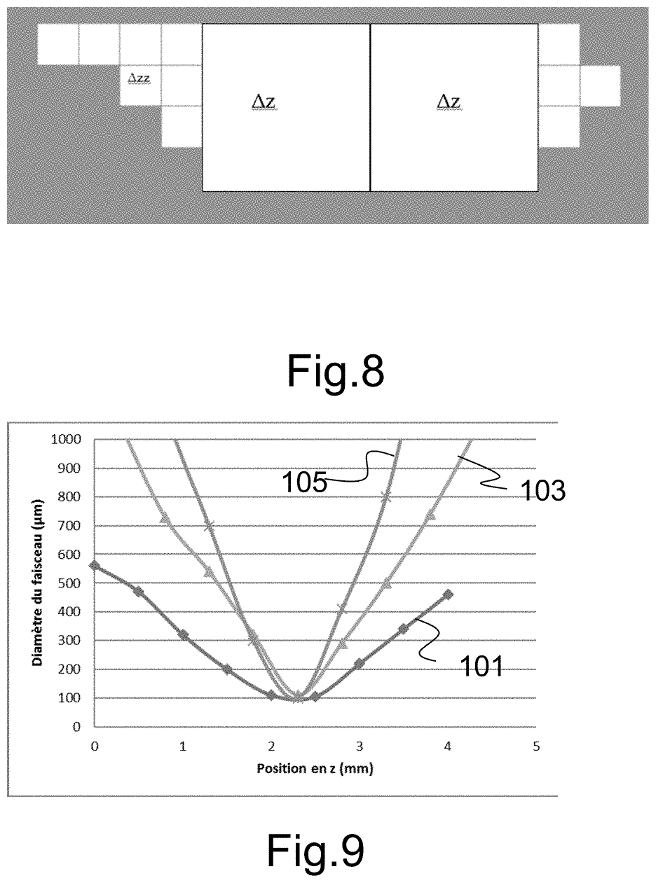

This is represented schematically in FIG. 8. For simplification of presentation, it is assumed that the voxels are cubes and that there is, for example, at least a first resolution that makes it possible to produce voxels of size Δz and a finer second resolution that makes it possible to produce voxels Δzz of smaller size, for example 10*Δzz=Δz.

It is easily understood that if the voxels inside the three-dimensional object are produced with the resolution Δz and the voxels forming the outer surface of the three-dimensional object are produced with the resolution Δzz, it is possible to reduce the fabrication time of the three-dimensional object significantly.

According to one particular embodiment of the invention, the fabrication of the three-dimensional object 3 may be carried out successively, the inner volume being polymerized using a composition 11 comprising fillers 20 in the form of transparent particles of large dimensions that make it possible to obtain a high voxel size relative to the object 3 to be fabricated. The inner portion of the object is then removed from the vessel 9 comprising the composition 11. The inner portion is then immersed in a vessel 9 comprising a second composition 11 comprising transparent particles of finer dimensions than the preceding composition 11 or even containing no particles for the polymerization of the outer surface of the object 3. These successive compositions 11 making it possible to reduce the size of the voxels as a function of the finish of the three-dimensional object 3 to be formed. The process thus makes it possible to polymerize at locations located in the inner volume with a lower resolution than the locations forming the outer surface of the three-dimensional object.

Of course, it is possible to generalize this process and to make provision to produce various portions of the three-dimensional object 3 successively by polymerization in various vessels 9 each containing a specific composition 11 that makes it possible to obtain a predetermined voxel size.

The process according to the invention thus makes it possible to easily and rapidly produce three-dimensional objects 3, the shape of which may be more complex than the shape attainable with conventional stereolithography methods. It is thus possible to envisage the fabrication of complex objects having centimeter-size dimensions, or even around ten centimeters in size with a reasonable fabrication time and without using holding elements.

This process therefore has a decisive advantage relative to single-photon SLA since the layer thickness cannot, in general, be modified easily during the polymerization of a layer of resin: although it is possible to modify the size of the light spot, only two space (voxel) parameters can be modified, whereas according to the process that is the subject of the invention makes it possible to adjust the size of the voxels as a function of three parameters, the diameter of the voxel, and the depth and the power of the light source 5 for producing an object according to a setpoint taking into account the surface finish.

According to a particular embodiment of the invention, the process of the invention is a bio-printing process, in which case the composition 11 comprises monomers, fillers, biological materials and a hydrogel.

As a nonlimiting example of the invention, the monomers 12 used are selected from L-lactic acid, glycolic acid, caprolactones, considered alone or as a mixture. The photoinitiator may be selected from aromatic ketones, such as benzophenone or Irgacure.

The fillers 20 comprise living cells. According to one particularly favorable embodiment, the fillers 20 are composed of “beads” comprising said cells, these beads being for example a mixture of collagen and living cells.

A hydrogel is necessary in order to preserve the viability of the cells during the printing. As a nonlimiting example of the invention, the hydrogel may be selected from collagen, gelatin, fibrin, alginate, chitin, chitosan, hyaluronic acid, poly-(2-hydroxyethyl methacrylate) (PHEMA), polyvinyl alcohol (PVA) and polyethylene glycol (PEG) considered alone or as a mixture.

The removal of a printed object from the vessel in the presence of filler 20 in the form of beads or particles may be carried out conventionally by removal using pliers, or else with a screen, and the supernumerary particles that form, with the unpolymerized monomer resin, a film on the object removed, can then be eliminated by wiping or by means of a bath or rinsing with a solvent which dissolves the unpolymerized resin, which step is generally already carried out at the end of bulk resin printings. In certain cases, the unpolymerized resin may be fluidized by adding liquid monomer which allows recycling of the unconverted materials or with the aid of a conventional solvent of the monomer.

In particular, even if the beads or particles of the filler 20 had to be in mutual contact (maximum filler density) or even in a compact stack, the resin gets into the remaining hollows and, by polymerizing, binds the particle around points where the laser will have been focused. The particles at the periphery, not bonded or insufficiently bonded by polymerization are then removed during a solvent rinsing.

### EXAMPLES

### Example 1 (Compositions)

### Monomers

The following monomers and compositions are particularly suitable for the invention:

| | | | Refractive | |
|---|---|---|---|---|
| | | | index | |
| Reference | Manufacturer | Composition | measured | Viscosity |
| PEGDA | Servilab | Poly(ethylene | 1.468 | 0.05 Pa · s |
| 575 | (SIGMA) | glycol) diacrylate | | |
| TEGDA | Servilab | Tri(ethylene glycol) | 1.4585 | 0.02 Pa · s |
| | (SIGMA) | diacrylate 95% | | |
| PETA | Servilab | Pentaerythritol | 1.484 | 0.60 Pa · s |
| | (SIGMA) | tetraacrylate | | |
| HDDA | Servilab | 1,6-hexanediol | 1.456 | 0.02 Pa · s |
| | (SIGMA) | diacrylate | | |
| Norland | Thorlab | | 1.499 | 1.20 Pa · s |
| 65 | (Norland) | | | |
| Norland | Thorlab | | 1.523 | 0.30 Pa · s |
| 81 | (Norland) | | | |

The refractive indices were measured by an Abbe refractometer (Kern Optics ORT 1RS Refractometer) calibrated using a calibration oil.

### Transparent Particle Fillers

| | | | | | Refrac- |
|---|---|---|---|---|---|
| | | | | | tive |
| Reference | Manufacturer | Composition | Diameter | | index |
| Borosilicate | Sigma- | Borosilicate | 1 | mm | 1.47 |
| solid-glass | Aldrich | | | | |
| beads | | | | | |
| Glass beads, | Sigma- | Soda-lime | 700-1200 | μm | 1.52 |
| acid washed | Aldrich | glass | | | |

The values of the refractive indices were estimated from bibliographic data such as (http://refractiveindex.info/), SCHOTT optical glass data sheets 2015 Jul. 22, or M. Rubin, Optical properties of soda lime silica glasses, Solar Energy Materials 12, 275-288 (1985).

Examples of compositions according to the invention:

### Composition 1

| | Compound | Refractive index |
|---|---|---|
| Monomer | PEGDA (575) | 1.47 |
| Photoinitiator | IRAGACURE 651 | Negligible influence |
| Filler (50% of the volume | Borosilicate solid- | 1.47 |
| of the total composition) | glass beads (diameter | |
| | 1 mm) | |

### Composition 2

| | Compound | Refractive index |
|---|---|---|
| Resin | Norland 81 | 1.523 |
| Filler (50% of the volume | Glass beads, acid | 1.52 |
| of the total composition) | washed (700-1200 μm) | |

The Norland resins incorporate a photoinitiator and were used without addition of complementary initiator.

### Composition 3

The value of the refractive index being defined by the relation:

n=n₁·α+n₂(1−α)

with n₁ the refractive index of the compound 1, n₂ the refractive index of the compound 2 and α the portion by weight of compound 1 in composition 11.

The following composition is an example according to the invention.

| | Compound | Refractive index |
|---|---|---|
| Monomer (47.5% of the | PEGDA | 1.47 |
| volume of the total | | |
| composition) | | |
| Resin (2.5% of the volume | Norland 65 | 1.499 |
| of the total composition) | | |
| Photoinitiator | IRGACURE 651 | Negligible influence |
| Filler (50% of the volume | Borosilicate solid- | 1.52 |
| of the total composition) | glass beads (diameter | |
| | 1 mm) | |

This composition was polymerized by 2-photon polymerization using a frequency-doubled Yb:KGW laser at 515 nm with pulse durations of 500 fs to obtain an object, in the form of a double bar, of 9 mm.

Compositions 1-3 have a satisfactory viscosity for preventing movements of the object to be printed and have a low variation of the refractive index of these various components. The compositions are also transparent to the predetermined photopolymerization wavelength.

### Example 2 (Variable Voxels)

An experiment was carried out in order to determine the effects of diffusers placed at the entrance of the objective and making it possible to have a wide range of spatial frequencies. Specifically, if the initial beam is characterized as a flat wave propagating in a certain direction, the diffuser separates this wave into multiple waves propagating randomly in a characteristic angle of the diffuser (link to the roughness or “spatial frequency”).

The device comprises an He/Ne laser with a wavelength of 543 nm, an objective with a long working distance and a set of various diffusers mounted on a filter wheel.

The measurement of the laser beam caustic is reported in FIG. 9. These measurements make it possible to determine the influence of the diffusers on the diameter of the laser beam.

Represented in this FIG. 9 are three curves 101, 103 and 105. Curve 101 shows the diameter of the beam in μm as a function of the z position in mm without diffuser, curve 103 with a 1° diffuser and curve 105 with a 10° diffuser.

It is observed that this method makes it possible to control the depth of field of the Gaussian beam without reducing the diameter of the beam at the focal point and thus to control the dimensions of the voxel.

In the present case, the diameter of the beam may attain 100 μm in diameter and a depth of field defined by an increase in diameter of 2^{0.5}, of around 300 μm, i.e. a diameter:depth ratio of the order of 0.3 (FIG. 7).

1-19. (canceled)

20. A method comprising producing a three-dimensional object, wherein producing said three-dimensional object comprises introducing a composition into a polymerization vessel and, at predetermined locations, polymerizing said composition by multiphoton photopolymerization to produce said three-dimensional object, wherein said composition comprises a monomer, a filler, and a photoinitiator, wherein said difference between refractive indices of said monomer and of said filler present is less than 0.05, wherein said composition has a viscosity that is greater than or equal to 0.05 Pa·s, and wherein said composition is transparent to said photopolymerization wavelength.

21. The method of claim 20, wherein said viscosity is greater than or equal to 0.30 Pa·s.

22. The method of claim 20, wherein said filler comprises transparent particles.

23. The method of claim 22, wherein said composition comprises from 10 to 70% by volume of transparent particles.

24. The method of claim 22, wherein said transparent particles are spherical particles.

25. The method of claim 22, wherein said transparent particles are made of a material selected from the group consisting of silica, glass, borosilicate glass, and soda-lime glass.

26. The method of claim 22, wherein said transparent particles are made of a polymer that is insoluble in said composition.

27. The method as claimed claim 20, wherein said filler comprises at least one component that is soluble in said composition.

28. The method of claim 20, wherein said composition comprises monomers selected from the group consisting of L-lactic acid, glycolic acid, caprolactones, considered alone or as a mixture, fillers comprising living cells, a hydrogel selected from collagen, gelatin, fibrin, alginate, chitin, chitosan, hyaluronic acid, poly-(2-hydroxyethyl methacrylate) (PHEMA), polyvinyl alcohol (PVA), and polyethylene glycol (PEG) considered alone or as a mixture.

29. The method of claim 20, wherein said monomer is an acrylic monomer.

30. The method of claim 29, wherein said acrylic monomer is selected from the group consisting of poly(ethylene glycol) diacrylate, tri(ethylene glycol) dimethacrylate, pentaerythritol tetraacrylate, 1,6-hexanediol diacrylate, or in combination.

31. The method of claim 29, wherein said photoinitiator is selected from the group consisting of an aromatic ketone, an aromatic derivative, eosin Y, and a xanthene dye.

32. The method of claim 20, wherein said composition comprises an epoxy monomer.

33. The method of claim 32, wherein said photoinitiator is an onium salt.

34. The method of claim 20, further comprising carrying out said multiphoton photopolymerization using a laser beam along which an optical diffuser has been placed to adapt a polymerization spatial resolution.

35. The method of claim 22, wherein said three-dimensional object comprises an outer surface and an inner volume, wherein said method further comprises polymerizing locations in said inner volume with a resolution that is lower than locations forming said outer surface.

36. The method of claim 35, further comprising successively polymerizing various portions of said three-dimensional object in various vessels, each of which contains a specific composition that makes it possible to obtain a voxel size, or even functionalities that are predetermined.

37. The method of claim 22, wherein said three-dimensional object comprises an outer surface and an inner volume, wherein said method further comprises polymerizing said inner volume in a first vessel containing a first composition comprising first fillers having transparent particles, thereby making it possible to obtain a first voxel size and polymerizing an outer part of said object in a second vessel, wherein said second vessel contains a second composition comprising either second fillers comprising transparent particles or no filler, thereby making it possible to obtain a second voxel-size that is smaller than said first voxel size.

38. An apparatus for producing a three-dimensional object by multiphoton photopolymerization, said comprising a laser, a focusing device, a displacement unit, a polymerization vessel, and a polymerization resolution adapter, wherein said polymerization vessel contains a composition, wherein said composition comprises a monomer, a filler, and a photoinitiator, wherein refractive indices of said monomer and said filler differ by less than 0.05, wherein said composition has a viscosity that exceeds 0.05 Pascal-seconds, wherein said composition is transparent to a wavelength at which said photopolymerization takes place, wherein said focusing device focuses a laser beam produced by said laser and adapts a numerical aperture thereof, wherein said displacement unit is configured to enable focusing of said laser beam inside said polymerization vessel to permit polymerizing said composition at predetermined locations to produce said three-dimensional object, and wherein said polymerization resolution adapter comprises a diffuser movably mounted on a support to be placed on an optical path or outside of said laser beam in order to adapt said polymerization resolution.
